(19) United States
(12) Patent Application Publication
(10) Pub. No.: US 2021/0175360 A1
(43) Pub. Date: Jun. 10, 2021

(54) THIN FILM TRANSISTOR AND METHOD FOR MANUFACTURING THE SAME

(71) Applicant: BOE TECHNOLOGY GROUP CO., LTD., Beijing (CN)

(72) Inventor: Pengfei GU, Beijing (CN)

(21) Appl. No.: 15/779,970

(22) PCT Filed: Oct. 13, 2017
(86) PCT No.: PCT/CN2017/105993

§ 371 Date: May 30, 2018

(30) Foreign Application Priority Data
Apr. 24, 2017 (CN) 201710272455.2

(51) Int. Cl. H01L 29/786; H01L 29/66; H01L 29/40

(52) U.S. Cl. CPC H01L 29/7869; H01L 29/401; H01L 29/66969

(57) ABSTRACT

The present disclosure relates to a TFT and a method for manufacturing the TFT. The method includes forming an active layer; forming a gate electrode insulating layer on the active layer; forming a gate electrode on the gate electrode insulating layer; forming an interlayer insulating layer on the gate electrode to cover the gate electrode and the active layer, so that an interface between the interlayer insulating layer and the active layer possesses a donor-like defect state; forming a via hole in the interlayer insulating layer so that the active layer is exposed; and forming a source electrode and a drain electrode on the interlayer insulating layer, so that the source electrode and the drain electrode are electrically coupled to the active layer through the via hole, respectively.

### CROSS REFERENCE

This application is based upon and claims priority to Chinese Patent Application No. 201710272455.2 and titled as “Thin Film Transistor and Method for Manufacturing the Same”, filed on Apr. 24, 2017, the entire contents thereof are incorporated herein by reference.

### TECHNICAL FIELD

The present disclosure relates to a display technical field, and more particularly, to a TFT for reducing a resistance between a source electrode/drain electrode and a channel area and a method for manufacturing the TFT.

### BACKGROUND

At present, various panel displays have been developed. In the panel display, a thin film transistor (TFT) is generally used as a switch of a pixel to control switching on and off of a driving signal. For example, a TFT-LCD using the TFT has advantages, such as small volume, low power consumption, and no radiation, and thereby being developed rapidly in recent years, so that the TFT-LCD has become a mainstream of displays in the market, and is widely used in mobile phones, tablets, notebooks and other electronic devices.

The TFT generally includes a gate electrode, an active layer, a source electrode, and a drain electrode, wherein a portion of the active layer corresponding to the gate electrode constitutes a channel area. The source electrode and the drain electrode are electrically coupled to the channel area, respectively, to control switching on and off of the channel area by using the gate electrode, so as to realize switching on/off between the source electrode and the drain electrode. In most cases, due to structural constraints, the source electrode and the drain electrode cannot be in direct contact with the channel area of the active layer, but can be coupled to the channel area through other portions of the active layer. In this case, the resistance of the active layer is relatively higher, so that the resistance between the source electrode/drain electrode and the channel area is higher, so that a higher driving voltage is required, which causes power consumption increased and heat-generation amount increase, and other problems.

### SUMMARY

According to a first aspect of the present disclosure, a method for manufacturing a TFT includes:

forming an active layer;

forming a gate electrode insulating layer on the active layer;

forming a gate electrode on the gate electrode insulating layer;

forming an interlayer insulating layer on the gate electrode to cover the gate electrode and the active layer, so that an interface between the interlayer insulating layer and the active layer possesses a donor-like defect state;

forming a via hole in the interlayer insulating layer so that the active layer is exposed; and

forming a source electrode and a drain electrode on the interlayer insulating layer, so that the source electrode and the drain electrode are electrically coupled to the active layer through the via hole, respectively.

In one embodiment, the method further includes:

making a portion of the active layer that is in contact with the interlayer insulating layer conductive, by an annealing process.

In one embodiment, a step of forming the interlayer insulating layer includes:

depositing a material of the interlayer insulating layer on the gate electrode, so that an oxygen content in the interlayer insulating layer is lower than an oxygen content of a standard stoichiometric ratio, wherein the oxygen content of the standard stoichiometric ratio represents the oxygen content in the interlayer insulating layer obtained by calculating chemical composition of a material of the interlayer insulating layer.

In one embodiment, the step of forming the interlayer insulating layer comprises:

co-depositing two or more sources on the gate electrode to form an insulating oxide;

calculating a supply amount of the two or more sources based on a chemical reaction equation by using reaction of the two or more sources to generate the insulating oxide, according to the standard stoichiometric ratio of the insulating oxide;

controlling the supply amount of the source with a high oxygen content of the two or more sources below the calculated supply amount.

In one embodiment, the step of forming the interlayer insulating layer comprises:

co-depositing N₂O and SiH₄ on the gate electrode, wherein a ratio of the N₂O to the SiH₄ is about 30:1 or even lower.

In one embodiment, the volume flow ratio of the N₂O to the SiH₄ is about 10:1 or even lower.

In one embodiment, the deposition is executed by enhancing PECVD using a plasma.

In one embodiment, a support amount of the source is controlled by changing film-forming parameters of a depositing process.

In one embodiment, the film-forming parameter includes temperature, pressure and/or amount of using gas.

In one embodiment, the active layer includes Indium Gallium Zinc Oxide (IGZO).

According to a second aspect of the present disclosure, a TFT includes:

a substrate;

an active layer that is formed on the substrate;

a gate electrode insulating layer that is formed on the active layer and covers a portion of the active layer;

a gate electrode that is formed on the gate electrode insulating layer;

an interlayer insulating layer that is formed on the gate electrode and covers the gate electrode and the active layer;

a source electrode and a drain electrode that are formed on the interlayer insulating layer, and are electrically coupled to the active layer through a via hole formed in the interlayer insulating layer,

wherein, an interface between the interlayer insulating layer and the active layer possesses a donor-like defect state.

In one implementation, the donor-like defect state includes an oxygen vacancy.

In one implementation, the interlayer insulating layer includes an insulating oxide, wherein an oxygen content in the insulating oxide is lower than an oxygen content calculated according to a standard stoichiometric ratio of the insulating oxide, wherein the oxygen content calculated according to the standard stoichiometric ratio of the insulating oxide represents an oxygen content in the interlayer insulating layer obtained by calculating chemical composition of the insulating oxide.

In one implementation, the interlayer insulating layer is formed by co-depositing N₂O and SiH₄, wherein a ratio of the N₂O to the SiH₄ is about 30:1 or even lower.

In one implementation, the volume flow ratio of the N₂O to the SiH₄ is about 10:1 or even lower.

In on implementation, the active layer comprises IGZO.

### BRIEF DESCRIPTION OF THE DRAWINGS

The accompanying drawings, which are included to provide a further understanding of the present disclosure and constitute a part of the specification, illustrate embodiment(s) of the disclosure together with following exemplary implementations, but not constitute to limit the present disclosure. In the drawings:

FIG. 1 is a sectional view of a TFT according to one embodiment of the present disclosure;

FIG. 2 to FIG. 7 are sectional views showing various stages of a method for manufacturing the TFT according to one embodiment of the present disclosure;

FIG. 8 to FIG. 10 are voltage-current relationship graphs according to one embodiment of the present disclosure.

### DETAILED DESCRIPTION

In order to enable those skilled in the art to understand the technical solution of the present disclosure, a TFT and a method for manufacturing the TFT as provided by the present disclosure will be further described in detail below in conjunction with the accompanying drawings and the exemplary embodiments. Obviously, the embodiments merely refer to a part of the embodiments of the present disclosure but not all of the embodiments. Based on the embodiments of the present disclosure, all other embodiments obtained by those skilled in the art without making creative efforts shall fall within the protection scope of the present disclosure.

Unless otherwise defined, the technical terms or scientific terms used herein should be general meanings as comprehended by the persons with ordinary skill in the art of the present disclosure. The “first”, “second” and similar words used in the specification and claims of the present disclosure do not refer to any order, number, or importance, but only used to distinguish the different components. Similarly, “one” or “a” or the like does not mean to limit the number but means that there is at least one. The word “connect” and the like are not limited to physical or mechanical connection, but may include electrical connection, no matter whether direct or indirect. Words like “up”, “down”, “left”, “right” and the like are only used to indicate relative positional relationship, so if the absolute position of the described object changes, the relative positional relationship also changes accordingly.

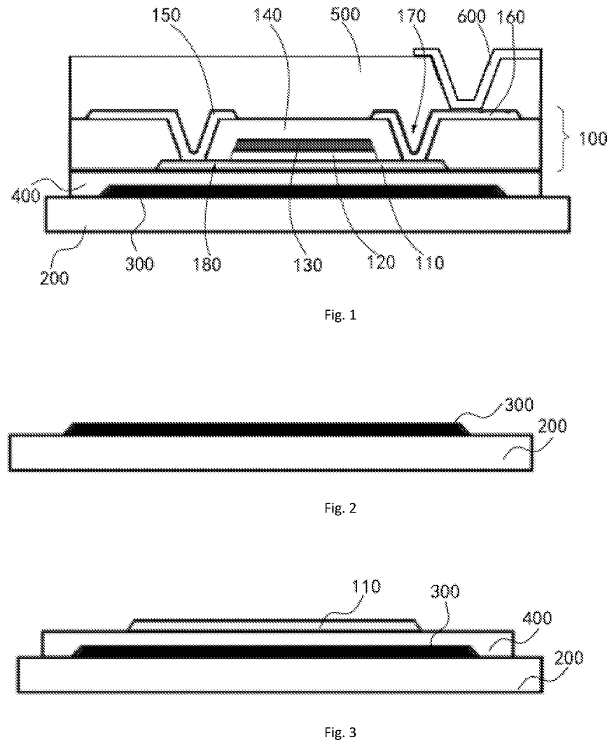

FIG. 1 is a sectional view of a TFT according to one embodiment of the present disclosure. Referring to FIG. 1, the TFT 100 according to one embodiment of the present disclosure includes an active layer 110, a gate insulating layer 120, a gate electrode 130, an interlayer insulating layer 140, a source electrode 150, and a drain electrode 160.

The active layer 110 may be formed on a substrate, such as a glass substrate, an organic substrate, a flexible substrate, or the like. However, the present disclosure is not limited thereto, and the active layer 110 may be formed on any other structure that can function as a base. In one embodiment of the present disclosure, as shown in FIG. 1, the active layer 110 may be formed on a substrate 200.

The active layer 110 is formed of a semiconductor material, and the active layer 110 may be formed on the substrate 200 by a patterning process. For example, it is possible to coat a material layer of the active layer on the substrate 200 and then pattern the material layer to form a desired active layer pattern. The patterning may be accomplished by processes, such as a photoresist coating, exposure, development, etching, and stripping. The active layer 110 may be formed using any patterning process available in the art, which will be omitted herein.

The gate electrode insulating layer 120 is formed on the active layer 110, and is patterned to cover a channel area of the active layer 110. A method of forming the gate electrode insulation layer 120 may be similar to the aforesaid method of forming the active layer 110, that is, the gate electrode insulating layer 120 is formed by coating the material layer of the gate electrode insulating layer and then patterning the material layer.

The gate electrode 130 is formed on the gate electrode insulating layer 120, corresponding to the channel area. The gate electrode is generally formed of a metal material, however, this embodiment is not limited thereto.

The interlayer insulating layer 140 is formed on gate electrode 130, and covers the gate electrode 130 and the active layer 110. A via hole 170 is formed in the interlayer insulating layer 140, so that the active layer 110 is exposed. There is a certain distance between a portion of the active layer 110 exposed through the via hole 170 and the channel area. The portion of the active layer 110 located between the via hole 170 and the channel area may be in contact with the interlayer insulating layer 140.

A source electrode 150 and a drain electrode 160 are formed on the interlayer insulating layer, and respectively from an electrical connection with the active layer 110 through the via hole 170.

According to this embodiment, the active layer 110, the gate electrode insulating layer 120, the gate electrode 130, the source electrode 150 and the drain electrode 160 may be formed by using the materials and method as learned by the person skilled in the art, which will be omitted herein.

In this embodiment, an interface portion where the interlayer insulating layer 140 is in contact with the active layer 110, for example, an interface 180 as shown in FIG. 1 may be formed to have a donor-like defect state (i.e., a donor-like state). The donor-like state is presented to be electricalneutral when an energy level is occupied by electrons, and presented to be electricalpositive when the energy level releases the electrons, also called as a donor-like surface state. When the interface 180 has a donor-like defect state, density of a carrier in the active layer 110 can be increased in a subsequent process, such as an annealing process, so that the active layer 110 can be locally conductive.

Local conduction of the active layer 110 by using the annealing process has been described in the foregoing embodiments, but the present disclosure is not limited thereto, and the local conduction of the active layer 110 may also be achieved by using the other processes. For example, it is possible not to perform the annealing process independently after forming the TFT, rather, to make the active layer 110 locally conductive in the other annealing or heat-treating processes in the subsequent processes.

According to this embodiment, the TFT 100 may be directly formed on the substrate 200, and other auxiliary layers may be formed between the TFT 100 and the substrate 200. For example, as shown in FIG. 1, a light shielding layer 300 and a planarization layer 400 may be also formed between the substrate 200 and the TFT, however, the present disclosure is not limited thereto.

A pixel electrode 600 may be formed on the planarization layer 500, and the pixel electrode 600 may be coupled to the drain electrode 160 through the via hole in the planarization layer 500, so as to receive driving signal from the drain electrode 160.

The above-described planarization layer 500 is merely an example, and the present disclosure is not limited thereto. For example, in a practical use, the planarization layer 500 may also include other structures such as a pixel defining layer, which will be omitted herein.

In the above embodiments, the TFT 100 may be used in the LCD, however, the present disclosure is not limited thereto. The above-described structure of the TFT 100 may also used in other switch device, for example, in an organic light-emitting diode (OLED) display.

Hereinafter, a method of manufacturing the TFT according to an embodiment of the present disclosure will be described in more detail with reference to FIG. 2 to FIG. 7.

As shown in FIG. 2, in this embodiment, the light shielding layer 300 is formed on the substrate 200. The substrate 200 may be a glass substrate or an organic plastic material substrate. The present disclosure does not make any particular limitation thereto. The light shielding layer 300 for blocking light transmission may be formed at a location corresponding to the TFT 100. The light shielding layer 300 is provided to prevent illumination from affecting characteristics of the active layer 110 (e.g. IGZO layer). The light shielding layer 300 may be formed of an opaque metal or a metal oxide, or may be formed of an organic film, such as a black matrix (BM) or a color film (for example, a red color film).

In addition, when the TFT 100 is used in the LCD, the light shielding layer may also prevent light from transmitting from the location of the TFT 100, so that a user cannot see the TFT 100, and thereby being good for displaying clear images. However, the present disclosure is not limited thereto. The light shielding layer 300 may also formed in the other layers, may be omitted or replaced by other structures.

As shown in FIG. 3, a planarization layer 400 may be formed on the light shielding layer 300, and then the active layer 110 is formed on the planarization layer 400. The planarization layer 400 covers the surface of the light shielding layer 300, to provide a planar surface to be used to form the TFT 100. The planarization layer 400 may also used as a buffer layer to avoid lattice mismatch between the substrate 200 and/or the light shielding layer 300 and the active layer 110. The planarization layer may be formed of insulating materials, such as silicon dioxide (SiO₂), and the active layer 110 may be formed of indium gallium zinc oxide (IGZO).

In this embodiment, the substrate 200, the light shielding layer 300 and the planarization layer 400 are entirely used as the substrate of the TFT 100, however, the present disclosure is not limited thereto. The TFT 100 may be used on the substrate in other forms.

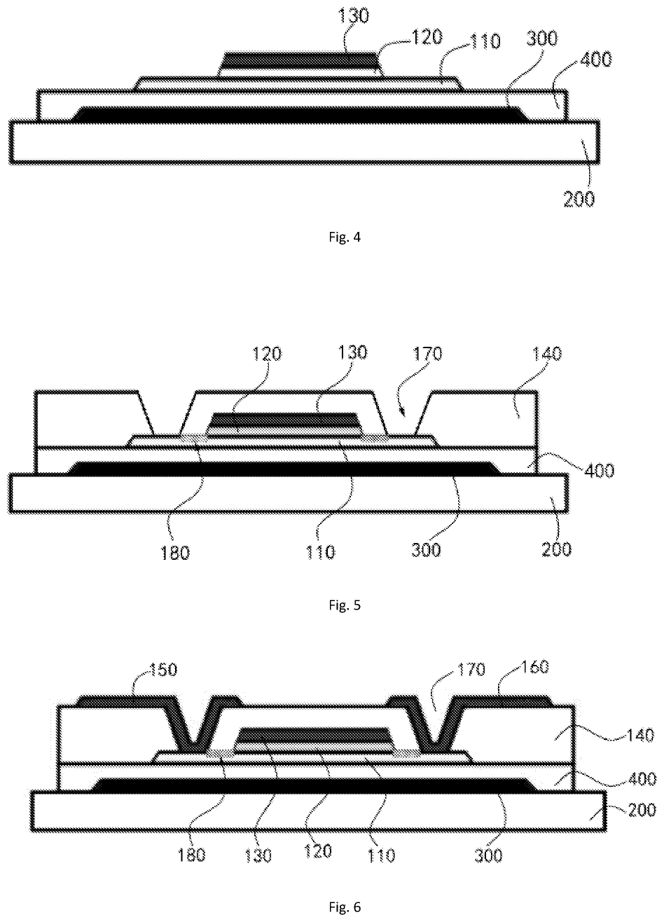

As shown in FIG. 4, the gate electrode insulating layer 120 and the gate electrode 130 are formed on the active layer 110. The gate electrode insulation layer 120 is used to insulate the gate electrode 130 from the active layer 110. The gate electrode insulating layer 120 may be in a single layer or in multiple layers, and may be formed of silicon oxide or nitride (SiOx or SiNx). The gate electrode 130 may have a single-layer or multi-layer structure, and may be formed of materials, such as Mo, Cu, Al, Nd. The portion of the active layer 110 corresponding to the gate electrode 130 is configured as the channel area of the TFT.

As shown in FIG. 5, the interlayer insulating layer 140 is formed on the structure in FIG. 4, and the via hole 170 is formed in the interlayer insulating layer 140, so that a portion of the active layer 110 is exposed. There is a certain distance between the portion of the active layer 110 exposed through the via hole 170 and the channel area. The portion of the active layer 110 located between the via hole 170 and the channel area may be in contact with the interlayer insulating layer 140.

In this embodiment, the interface portion of the interlayer insulating layer 140 in contact with the active layer 110, for example, the interface 180 as shown in FIG. 5 may be formed to have a donor-like defect state (i.e., a donor-like state). The donor-like state is presented to be electricalneutral when an energy level is occupied by electrons, and presented to be electricalpositive when the energy level releases the electrons, also called as a donor-like surface state. When the interface 180 has a donor-like defect state, density of a carrier in the active layer 110 can be increased in a subsequent process, such as an annealing process, so that the active layer 110 can be locally conductive.

Local conduction of the active layer 110 by using the annealing process has been described in the foregoing embodiments, but the present disclosure is not limited thereto, and the local conduction of the active layer 110 may also be achieved by using the other processes. For example, it is possible not to perform the annealing process independently after forming the TFT, rather, to make the active layer 110 locally conductive in the other annealing or heat-treating processes in the subsequent processes.

The donor-like defect state may be implemented in a variety of ways. Hereinafter, the implementation of the donor-like defect state will be described in more details by taking an example of the oxygen vacancy. However, it should be appreciated for those skilled in the art that the present disclosure is not limited to occurrence of the oxygen vacancy defect.

In one embodiment, a method for generating the oxygen vacancy defect at the interface 180 may include: depositing materials of the interlayer insulating layer on the gate electrode so that oxygen content in the formed interlayer insulating layer is lower than the oxygen content of a standard stoichiometric ratio.

In this embodiment, the standard stoichiometric oxygen content represents the oxygen content of the interlayer insulating layer obtained by calculating chemical composition of the materials of the interlayer insulating layer. For example, the interlayer insulating layer 140 may be formed of an insulating oxide, for example a silicon oxide. In this case, the oxygen content of the standard stoichiometric ratio represents the oxygen content obtained by calculating the chemical composition of the silicon oxide.

Therefore, according to this embodiment, forming the interlayer insulation layer 140 may include following steps of: co-depositing two or more sources on the gate electrode 130 to form the insulating oxide; calculating a supply amount of the two or more sources based on a chemical reaction equation by using reaction of the two or more sources to generate the insulating oxide, according to the standard stoichiometric ratio of the insulating oxide; and controlling the supply amount of the source with a high oxygen content of the two or more sources below the calculated supply amount.

As an example, an interlayer insulating layer of the oxide containing silicon may be formed by co-depositing N₂O and SiH₄. The interlayer insulating layer 140 may be formed by enhancing chemical vapor deposition (PECVD) using a plasma. In this case, the interface 180 has an oxygen vacancy defect by reducing supply amount of the N₂O .

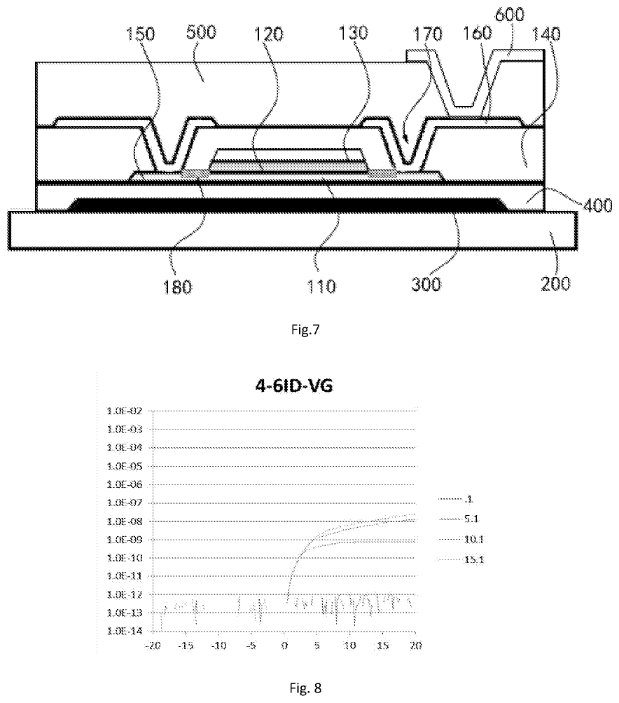

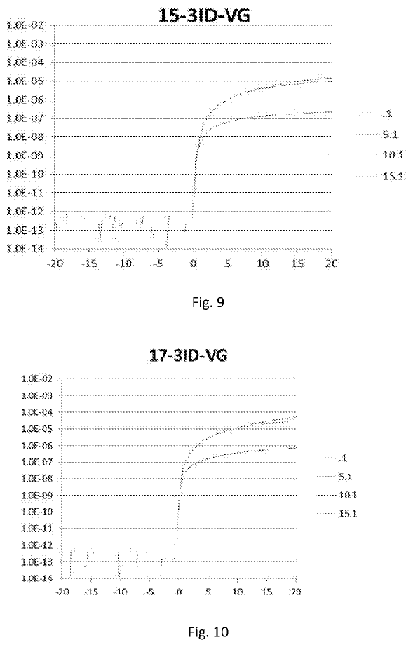

For example, referring to FIG. 8 to FIG. 10, FIG. 8, FIG. 9 and FIG. 10 respectively show a graph of current-voltage relationship at different ratios of N₂O and SiH₄. It can be seen from the drawings that as the supply amount of the N₂O decreases, for example, the ratio of N₂O to SiH₄ decreases from 40:1 in FIGS. 8 to 30:1 in FIG. 9 till to 20:1 in FIG. 10, the current level gradually increases, and thereby a degree of the conduction of the active layer 110 is gradually increased.

As an example, when the volume flow rate of SiH₄ is 50 sccm, and that of N₂O is 2000 sccm, the ratio of N₂O to SiH₄ is 40:1. In this situation, the current-voltage relationship is as shown in FIG. 8. When the volume flow ratio of N₂O to SiH₄ decreases to about 30:1 (as shown in FIG. 9), and even decreases to about 20:1 (as shown in FIG. 10), the current level gradually increases. In practical implementations, the volume flow ratio of N₂O to SiH₄ can be selected within the range of about 30:1 to 10:1, or optionally within the range of about 20:1 to 10:1, or even lower than 10:1 if necessary.

In this embodiment, the active layer 110 is formed of an indium gallium zinc oxide, which has an oxygen content of about 20%. Therefore, when the volume flow ratio of N₂O to SiH₄ is about 40:1, the oxygen content of the silicon oxide is substantially equal to the standard stoichiometry. It can be seen from FIG. 8 that the current level is lower, so that it is difficult to make the TFT normally conductive.

According to this embodiment, when the volume flow ratio of N₂O to SiH₄ is about 30:1 or even lower, the current level can reach the degree of normal switching of the TFT, thereby in one embodiment of the present disclosure, the volume flow ratio between N₂O and SiH₄ is determined to be about 30:1 or even lower. In this case, when the volume flow ratio of N₂O to SiH₄ is about 30:1 or even lower, a resistance between the source electrode/drain electrode and the channel can be reduced low enough, so that conduction of the corresponding portion of the active layer can be realized.

In another embodiment of the present disclosure, the volume flow ratio between N₂O and SiH₄ is determined to be about 10:1 or even lower. In this case, when the volume flow ratio of N₂O to SiH₄ is about 10:1 or even lower, the resistance between the source electrode/drain electrode and the channel can be reduced even lower, so that the conduction of the corresponding portion of the active layer can be realized.

In the above embodiments, the ratio between N₂O and SiH₄ is changed by means of adjustment of a ratio between volume and flow of N₂O and SiH₄ in the co-depositing process.

However, the present disclosure is not limited thereto. In one embodiment, the supply amount of respective sources can be controlled by changing film-forming parameter in the deposition process. For example, the film-forming parameter may include temperature, pressure and/or amount of using gas, etc., the present disclosure is not limited thereto.

After forming the above interlayer insulating layer, the structure as acquired may be annealed, so that the active layer 110 is conductive at the interface 180 where the interlayer insulation layer 140 is in contact with the active layer 110 (as shown by the shaded portion in FIG. 5). The conductive active layer 110 is located between the location of via hole 170 and the location of the channel area, so that the resistance between the electrode and the channel area can be reduced, when an electrode is formed in via hole 170.

Local conduction of the active layer 110 by using the annealing process has been described in the foregoing embodiments, but the present disclosure is not limited thereto, and the local conduction of the active layer 110 may also be achieved by using the other processes. For example, it is possible not to perform the annealing process independently after forming the TFT, rather, to make the active layer 110 locally conductive in the other annealing or heat-treating processes in the subsequent processes.

Further referring to FIG. 6, the source electrode 150 and the drain electrode 160 may be formed on the structure as acquired in FIG. 5, so that the source electrode 150 and the drain electrode 160 are electrically coupled to the active layer 110 through the via hole 170, thereby the TFT 100 according to this embodiment is accomplished. The source electrode 150 and the drain electrode 160 may have a single-layer or multi-layer structure, and may be formed of materials such as Mo, Cu, Al, and Nd.

Next, as shown in FIG. 7, other structures may also be formed on the TFT 100 so as to be applied to the display device. For example, in FIG. 7, the TFT 100 is used in a liquid crystal display (for example, the TFT-LCD).

A planarization layer 500 is formed on the TFT 100. A pixel electrode 600 is formed on the planarization layer 500. The pixel electrode 600 may be coupled to the drain electrode 160 through the via hole in the planarization layer 500, so as to receive the driving signal from the drain electrode 160.

The above-described planarization layer 500 is merely an example, and the present disclosure is not limited thereto. For example, in a practical use, the planarization layer 500 may also include other structures such as a pixel defining layer, which will be omitted herein.

In the foregoing embodiments, the TFT has a top-gate type structure. However, the present disclosure is not limited thereto. In other embodiments of the present disclosure, the TFT may also have gate electrode structures of other types.

By using the method of manufacturing the TFT of the present disclosure, the interface between the interlayer insulating layer and the active layer has the donor-like defect state, the portion of the active layer in contact with the interlayer insulating layer is conductive. The conductive portion of the active layer is disposed between the source electrode/drain electrode and the channel area, thereby reducing the resistance between the source electrode/drain electrode and the channel area.

It could be understood that the above embodiments are merely exemplary implementations as adopted for explaining the principle of the present disclosure, but the present disclosure is not limited thereto. For those skilled in the art, various variations and improvements may be made without departing from the spirit and essence of the present disclosure, and these variations and improvements are also considered to be within the protection scope of the present disclosure.

1. A method for manufacturing a thin film transistor, comprising:
forming an active layer;
forming a gate electrode insulating layer on the active layer;
forming a gate electrode on the gate electrode insulating layer;
forming an interlayer insulating layer on the gate electrode to cover the gate electrode and the active layer so that an interface between the interlayer insulating layer and the active layer possesses a donor-like defect state;
forming a via hole in the interlayer insulating layer so that the active layer is exposed; and
forming a source electrode and a drain electrode on the interlayer insulating layer so that the source electrode and the drain electrode are electrically coupled to the active layer through the via hole, respectively.

2. The method according to claim 1, further comprising:
making a portion of the active layer that is in contact with the interlayer insulating layer conductive by an annealing process.

3. The method according to claim 1, wherein the step of forming the interlayer insulating layer comprises:
depositing a material of the interlayer insulating layer on the gate electrode, so that an oxygen content in the interlayer insulating layer is lower than an oxygen content of a standard stoichiometric ratio, wherein the oxygen content of the standard stoichiometric ratio represents the oxygen content in the interlayer insulating layer obtained by calculating chemical composition of a material of the interlayer insulating layer.

4. The method according to claim 1, wherein the step of forming the interlayer insulating layer comprises:
co-depositing two or more sources on the gate electrode to form an insulating oxide;
calculating a supply amount of the two or more sources based on a chemical reaction equation by using reaction of the two or more sources to generate the insulating oxide, according to the standard stoichiometric ratio of the insulating oxide;
controlling the supply amount of the source with a high oxygen content of the two or more sources below the calculated supply amount.

5. The method according to claim 4, wherein the step of forming the interlayer insulating layer comprises:
co-depositing N₂O and SiH₄ on the gate electrode, wherein a volume flow ratio of the N₂O to the SiH₄ is about 30:1 or even lower.

6. The method according to claim 5, wherein the volume flow ratio of the N₂O to the SiH₄ is about 10:1 or even lower.

7. The method according to claim 4, wherein the support amount of the source is controlled by changing film-forming parameters of a depositing process.

8. The method according to claim 1, wherein the active layer comprises IGZO.

9. A thin film transistor (TFT), comprising:
a substrate;
an active layer, formed on the substrate;
a gate electrode insulating layer, formed on the active layer and covering a portion of the active layer;
a gate electrode, formed on the gate electrode insulating layer;
an interlayer insulating layer, formed on the gate electrode and covering the gate electrode and the active layer; and
a source electrode and a drain electrode, formed on the interlayer insulating layer, and electrically coupled to the active layer through a via hole formed in the interlayer insulating layer,
wherein an interface between the interlayer insulating layer and the active layer possesses a donor-like defect state.

10. The TFT according to claim 9, wherein the donor-like defect state comprises an oxygen vacancy.

11. The TFT according to claim 10, wherein the interlayer insulating layer comprises an insulating oxide, wherein an oxygen content in the insulating oxide is lower than an oxygen content calculated according to a standard stoichiometric ratio of the insulating oxide, wherein the oxygen content calculated according to the standard stoichiometric ratio of the insulating oxide represents an oxygen content in the interlayer insulating layer obtained by calculating chemical composition of the insulating oxide.

12. The TFT according to claim 10, wherein the interlayer insulating layer is formed by co-depositing N₂O and SiH₄, wherein a volume flow ratio of the N₂O to the SiH₄ is about 30:1 or even lower.

13. The TFT according to claim 12, wherein the volume flow ratio of the N₂O to the SiH₄ is about 10:1 or even lower.

14. The TFT according to claim 9, wherein the active layer comprises IGZO.

15. The method according to claim 5, wherein the volume flow ratio of the N₂O to the SiH₄ is within a range of about 30:1 to 10:1.

16. The method according to claim 15, wherein the volume flow ratio of the N₂O to the SiH₄ is within a range of about 20:1 to 10:1.

17. The TFT according to claim 12, wherein the volume flow ratio of the N₂O to the SiH₄ is within a range of about 30:1 to 10:1.

18. The TFT according to claim 17, wherein the volume flow ratio of the N₂O to the SiH₄ is within a range of about 20:1 to 10:1.

19. The method according to claim 5, wherein the support amount of the source is controlled by changing film-forming parameters of a depositing process.

20. The method according to claim 6, wherein the support amount of the source is controlled by changing film-forming parameters of a depositing process.
